(19) United States
(12) Patent Application Publication
(10) Pub. No.: US 2026/0112591 A1
(43) Pub. Date: Apr. 23, 2026

(54) Scanning Magnetron Device and Magnetron Sputtering Apparatus for PVD Planar Target

(71) Applicant: ARRAYED MATERIALS (CHINA) CO., LTD., Shenzhen (CN)

(72) Inventors: Hong Sheng Yang, Shenzhen (CN); Zuoxing Li, Shenzhen (CN); Xiaojun Zhang, Shenzhen (CN)

(21) Appl. No.: 19/148,046

(22) PCT Filed: May 29, 2023
(86) PCT No.: PCT/CN2023/096869

§ 371 Date: Jul. 15, 2025

(30) Foreign Application Priority Data
Jan. 16, 2023 (CN) 202310088521.6

(51) Int. Cl. H01J 37/34; C23C 14/35; C23C 14/50

(52) U.S. Cl. CPC H01J 37/3408; C23C 14/35; C23C 14/50; H01J 37/3455; H01J 2237/332

(57) ABSTRACT

Disclosed area magnetron device and magnetron sputtering apparatus. The magnetron device includes a magnetron including an outer magnetic pole and an inner magnetic pole, wherein the outer magnetic pole includes an outer linear portion and an outer semicircular portion connected to an end part of the outer linear portion, the inner magnetic pole includes an inner linear portion, and a gap is formed between the inner linear portion and the outer linear portion; and a driving device configured to drive the magnetron to reciprocate along a first direction and a second direction, wherein a distance L₁ that the magnetron scans along the first direction satisfies: L₁≥d, a distance L₂ that the magnetron scans along the second direction satisfies: 0.5d≤L₂≤2d, and d is a distance between center lines of the gaps on two sides of the inner linear portion of the magnetron.

### CROSS-REFERENCE TO RELATED APPLICATIONS

This application is the United States national phase of International Application No. PCT/CN2023/096869 filed May 29, 2023, and claims priority to Chinese Patent Application No. 202310088521.6 filed Jan. 16, 2023, the disclosures of which are hereby incorporated by reference in their entireties.

### BACKGROUND

### Technical Field

The present invention relates to the technical field of thin film deposition under vacuum, and in particular, to a scanning magnetron device and magnetron sputtering apparatus for Physical Vapor Deposition (PVD) using a planar target.

### Technical Considerations

Since the birth of magnetron sputtering deposition technology, the main issues of magnetron sputtering which have been the focus of many researchers include: target material utilization, deposition efficiency, film uniformity, film density, process stability during the deposition process, and meeting the various complex deposition requirements. For planar target magnetron sputtering, due to the effect of an orthogonal electromagnetic field on the sputtering ions, the sputtering ions are restricted in closed-loop magnetic field lines, and consequently, the sputtering of target material generates non-uniform target erosion. Once the target material is eroded and penetrated, the sputter target is scrapped; hence, the target material utilization has always been low, generally below 40%. The sputter target is a basic consumable material in the magnetron sputtering process, the usage amount is large, and the target material utilization plays an important role in the PVD thin film deposition process and the production cycle. Although the target material can be recycled, the target material utilization still has a great impact on the production cost and the improvement of the competitiveness of the final products. Therefore, it is necessary to seek to improve target material utilization, and many manufacturers have taken various measures to accomplish that.

The non-uniformity of erosion on the PVD target surface, i.e., the depth distribution of the erosion grooves, and the resulting problem of low target material utilization are due to the specific design and scanning trajectory of the magnetron. U.S. Pat. No. 7,186,319 by Yang et al. describes in detail how to improve target material utilization of a circular planar target by optimizing the design of a rotating planar magnetron. Circular planar targets are commonly used in PVD sputtering processes for 6-, 8-, and 12-inch wafers.

Over the past two decades, the magnetron sputtering technology using a rectangular planar target has been vigorously developed for fabricating flat panel displays, such as computer monitors and television screens. Magnetron sputtering is a preferred method for manufacturing conductive layers of display screens, where the conductive layers are made by depositing aluminum, molybdenum and a transparent conductor (such as indium tin oxide, i.e., ITO) onto a standard large-area rectangular panel glass or a polymeric sheet. The final manufactured panel may incorporate thin film transistors, plasma displays, field emitters, liquid crystal display (LCD) elements, or organic light emitting diodes (OLEDs). Similar technology can be used to deposit optical film layers for glass windows. The major difference between the magnetron sputtering using a rectangular planar target for relatively large rectangular substrates and the well-established magnetron sputtering technology for circular wafers lies in the large size of the former and the rectangular shape thereof, while the latter uses a relatively small circular planar target.

U.S. Pat. No. 5,565,071A by Demaray et al. describes a flat panel sputtering apparatus 20, as shown in FIG. 1. The disclosed film deposition chamber mainly includes: a vacuum chamber 22; a rectangular pedestal 24 that is typically electrically grounded; a rectangular glass panel or other substrate 26 supported by the pedestal 24; a rectangular planar target 28 that is in parallel with the substrate 26. At least the surface of the planar target 28 is composed of a metal to be sputtered and deposited onto the substrate. The planar target 28 is vacuum-sealed to the chamber 22 via an insulating plate 30.

A thin plate of the planar target 28 to be sputtered is typically bonded to a backing plate 32 in which cooling water channels are formed to cool the planar target 28. A sputtering gas, typically argon, flows into the vacuum chamber 22. Advantageously, a back chamber 34 is vacuum sealed to the back of the planar target backing plate 32 across an insulating plate 36 and pumped down to a low pressure with a mechanical vacuum pump. Thereby, the pressure differential across the planar target 28 and its backing plate 32 is substantially eliminated. The potential large amount of target deflection that might be caused by a large pressure differential is avoided. Thus, the large-area planar target 28 and the backing plate 32 thereof can be made thinner if needed.

Direct-current power supply applies a negative voltage to a cathode made of planar target 28, noting that the negative voltage is relative to a pedestal electrode, i.e., the pedestal 24, or other grounded component of the chamber such as shields, generating an electric field within the PVD vacuum chamber 22 for accelerating the Ar⁺ ions to sputter the target material and generating secondary electrons from the sputtering of the target material, where these electrons are used to create and sustain the plasma 38 near the target surface. The positive argon ions are attracted to the planar target 28 for sputtering and a portion of the sputtered metal atoms are deposited on the substrate 26 and thus a thin film is formed thereon that at least partially contains a material composition of the target material. Metal oxide or nitride can be deposited by additionally supplying oxygen or nitrogen gas into the vacuum chamber 22 during magnetron sputtering in a process known as “reactive magnetron sputtering”.

To increase the sputtering rate, a linear magnetron 40 with a bottom view illustrated in FIG. 2 is conventionally placed in the back of the backing plate 32 of the planar target 28. The linear magnetron has a center magnetic pole, or inner magnetic pole, 42 surrounded by an outer magnetic pole 44 of the opposite magnetic polarity, which generates a magnetic field parallel to the front sputtering surface of the planar target 28. The inner magnetic pole 42 is separated from the outer magnetic pole 44 by a substantially constant gap 46 corresponding to the high density closed-loop plasma 38 generated at the surface of the planar target 28. The outer magnetic pole 44 is composed of two outer linear portions 48 and two outer semicircular portions 50.

The linear magnetron 40 applies an external magnetic field to capture electrons and confine the plasma near the sputter target surface. Thereby, the density of the plasma and the sputtering rate of the planar target 28 increase significantly. A closed-loop shape of the magnetic field along a single closed trajectory creates a closed plasma loop that is generally formed along the gap 46 and effectively prevents plasma from leaking out at the two ends of an otherwise open loop. It should also be noted that the small size of the linear magnetron 40 relative to a size of the planar target 28 requires the linear magnetron 40 to scan linearly and reciprocally across the planar target 28 to achieve full face erosion of the target 28.

Typically, a lead screw mechanism easily drives a linear scan of a magnetron, as disclosed by Halsey et al. in U.S. Pat. No. 5,855,744. A magnetron assembly moves within a magnetron chamber, the magnetron assembly is supported on a central bearing support beam, and a set of bearing tracks support the magnetron assembly through a set of bearing members. Lateral movement of the magnetron assembly is produced by rotating a threaded drive rod that is engaged with a threaded drive nut contained in a threaded drive nut housing. The threaded drive nut housing is engaged and vertically slidable on a pair of connecting pins.

Coupled two-dimensional scanning of such linear magnetrons is described by De Bosscher et al. in U.S. Pat. Nos. 6,322,679 and 6,416,639. The magnetron described by De Bosscher et al. was originally developed for a rectangular panel having a dimension of about 400 mm×600 mm. However, for economic reasons of mass production scale and also for providing larger-area displays, the size of the panels has been increasing over the years and the size of the target materials has been increasing accordingly.

In one approach of accommodating larger-area sputter targets, a racetrack-shaped linear magnetron 40 in FIG. 2 is replicated up to 9 times laterally along a scanning direction to cover most of the target area, as shown in U.S. Pat. No. 5,458,759 by Hosokawa et al. However, this approach still requires magnetron scanning to average the magnetic field distribution.

U.S. Patent Application No. US2006/0049040A1 by Tepman discloses various magnetrons with a convoluted plasma loop, particularly having an overall rectangular profile. The magnetron can be arranged in a serpentine shape with parallel linear portions connected by curved portions; or arranged in a rectangular spiral shape with linear portions arranged in orthogonal directions. A plasma loop is formed between the inner and outer magnetic poles, the inner magnetic pole having a curled shape, the outer magnetic pole having a magnetic polarity opposite to that of the inner magnetic pole. FIGS. 3 and 4 are schematic design diagrams of magnetrons 52, 56 and the corresponding closed plasma loops 54 and 58, as provided by Tepman. Various magnetron scanning solutions were also provided by Tepman. However, it is still difficult to achieve uniform erosion of a large area of the sputter target using the magnetron and scanning solution proposed by Tepman. Furthermore, the magnetron and scanning solution proposed by Tepman does not address the full-face erosion of the four corners of a rectangular sputter target.

It can be seen from the foregoing that, in order to solve the problem of full-face erosion of the sputter target and the uniformity of deposited film on a rectangular substrate, the common practice is to reciprocate the magnetron relative to the sputter target in one direction, such as a first direction in FIG. 2. However, when the magnetron scans along the first direction, the two semicircular ends of the linear magnetron cause target erosion to a greater depth than the linear portion of the magnetron, resulting in relatively deep erosion grooves being formed in an edge portion of the sputter target. In summary, the design and scanning solution of the existing magnetron is not well optimized, and it is challenging to achieve the full-face erosion of the target material.

### SUMMARY

The present invention aims to solve at least one of the technical problems present in the existing technologies. In view of this, a scanning magnetron device for PVD (Physical Vapor Deposition) planar target is provided according to an embodiment of the present invention. The device can improve the erosion uniformity of the planar target, achieve the full face erosion of the target, and thereby, improve the utilization of the planar target.

In addition, a magnetron sputtering apparatus is provided according to another embodiment of the present invention.

According to an embodiment of the present invention, a scanning magnetron device is provided, which includes:
a magnetron, which includes an outer magnetic pole and an inner magnetic pole, where a polarity of the outer magnetic pole facing the target is opposite to that of the inner magnetic pole also facing the target, and the outer magnetic pole includes an outer linear portion and an outer semicircular portion connected to an end part of the outer linear portion, and the inner magnetic pole includes an inner linear portion and inner semicircular portion connected to an end part of the inner linear portion, and each of two opposite sides of the inner linear portion is provided with the outer linear portion, and a gap is formed between the inner linear portion and the outer linear portion, and at least the outer linear portion and the inner linear portion form a linear section of the magnetron, and at least the outer semicircular portion and the inner semicircular portion form a semicircular section of the magnetron; and
a driving device, which is configured to drive the magnetron to reciprocate along a first direction and a second direction, where the first direction is perpendicular to a linear direction along which the linear section extends, and the second direction is parallel to the linear direction along which the linear section extends;
and wherein a distance L₁ that the magnetron scans along the first direction satisfies: L₁≥d, a distance L₂ that the magnetron scans along the second direction satisfies: 0.5d≤L₂≤2d, and d is a distance between center lines of the gaps on two opposite sides of the inner linear portion.

The scanning magnetron device according to an embodiment of the present invention has at least the following beneficial effects. The magnetron according to this embodiment can improve the erosion uniformity of the planar target by reciprocating along the first direction and the second direction for a certain distance, so that the full-face erosion of the planar target is achieved, and the target utilization is improved.

In another embodiment of the present invention, scanning of the magnetron along the first direction is limited between an initial position and a first scanning limit position, and the scanning of the magnetron along the second direction is limited between another initial position and a second scanning limit position, and the magnetron is configured such that the semicircular section is concentric with a rounded corner of a planar target when the magnetron is at the first scanning limit position and the second scanning limit position.

In another embodiment of the present invention, the magnetron is configured such that an outer edge of the magnetron extends beyond a preset distance from an outer edge of the planar target when the magnetron is positioned at the first scanning limit position or the second scanning limit position.

In another embodiment of the present invention, a magnetic field strength generated by the inner magnetic pole is nearly equal to, or greater than, that generated by the outer magnetic pole. In another embodiment of the present invention, the magnetron further includes a middle magnetic pole, which includes a middle linear portion, and each magnet of the middle linear portion is arranged in the gap between the outer linear portion and the inner linear portion; and the outer linear portion, the inner linear portion and the middle linear portion include a plurality of magnets arranged along a second direction; and the magnets in the outer linear portion, the inner linear portion and the middle linear portion are symmetrically distributed with a center line of the inner linear portion as a symmetry axis; and a connection line of the north and south poles of the magnet in the outer linear portion and a connection line of the north and south poles of the magnet in the inner linear portion are perpendicular to the planar target; a connection line of the north and south poles of the magnet in the middle linear portion is parallel to the planar target; the two opposing magnetic poles of the magnet in the middle linear portion face the outer linear portion and the inner linear portion respectively, the magnetic pole at the outside of the magnet in the middle linear portion is consistent with the magnetic pole of the magnet in the outer magnetic pole facing the planar target, and the magnetic pole at the inside of the magnet in the middle linear portion is consistent with the magnetic pole of the magnet in the inner magnetic pole facing the planar target; and the linear section is composed at least of the outer linear portion, the inner linear portion and the middle linear portion, and the maximum magnetic field strength generated at the planar target surface by the linear section is greater than the maximum magnetic field strength generated at the planar target surface by the semicircular section.

In other embodiments of the present invention, an end part of the outer linear portion facing the outer semicircular portion includes a plurality of sets of outer magnets along a direction from the outer linear portion to the outer semicircular portion, and the magnetic field strength generated at the planar target surface by each of the plurality of sets of outer magnets decrease gradually from the first one of the plurality of outer magnets to the last one of the plurality of sets of outer magnets, and the maximum magnetic field strength generated at the planar target surface by the semicircular section is not greater than the magnetic field strength generated at the planar target surface by the last one of the plurality of outer magnets at the end part of the outer linear portion facing the outer semicircular portion.

In other embodiments of the present invention, along a direction from the outer linear portion to the outer semicircular portion, the outer linear portion includes at least one of the following arrangements:
a cross-sectional area of each set of the outer magnets parallel to the planar target decreases gradually from the first one of the plurality of sets of outer magnets to the last one of the plurality of sets of outer magnets;
a height of each set of the outer magnets decreases gradually from the first one of the plurality of sets of outer magnets to the last one of the plurality of sets of outer magnets;
a distance between each set of the outer magnets and the planar target increases gradually from the first one of the plurality of sets of outer magnets to the last one of the plurality of sets of outer magnets; or
each set of the outer magnets is made of different materials with magnetic field strength weakened gradually from the first one of the plurality of sets of outer magnets to the last one of the plurality of sets of outer magnets.

In other embodiments of the present invention, an end part of the inner linear portion facing the inner semicircular portion includes a plurality of sets of inner magnets corresponding to the plurality of sets of outer magnets, and along a direction from the inner linear portion to the inner semicircular portion, a distance between the side of each set of inner magnets facing the outer magnets and a center line of the inner linear portion increases gradually from a first one of the plurality of sets of inner magnets to a last one of the plurality of sets of inner magnets.

In other embodiments of the present invention, the inner magnetic pole further includes an inner semicircular portion; and the outer semicircular portion and the inner semicircular portion form the semicircular section; and an end part of the inner linear portion facing the semicircular section includes two inner magnet arrays, with each of the two inner magnet arrays including a plurality of sets of inner magnets, and the inner semicircular portion is connected to the end parts of the two inner magnet arrays, and a distance between adjacent inner magnet arrays increases gradually from a first one of inner magnet arrays to a last one of the inner magnet arrays, along a direction from the inner linear portion to the semicircular section.

In another embodiment of the present invention, the outer magnetic pole includes a first connecting unit, a plurality of outer linear portions and a plurality of outer semicircular portions; the plurality of outer linear portions are arranged in parallel along the first direction at intervals; one end of the adjacent outer linear portions is connected by the outer semicircular portion, and the other end of the two outer linear portions at outermost sides along the first direction is arc-connected with the first connecting unit; the inner magnetic pole includes a second connecting unit and a plurality of inner linear portions; the plurality of inner linear portions are arranged in parallel along the first direction at intervals; the outer linear portions and the inner linear portions are alternately distributed along the first direction, and one end of each inner linear portion facing the first connecting unit is connected through the second connecting unit.

According to another embodiment of the present invention, a magnetron sputtering apparatus is provided. The magnetron sputtering equipment includes:
a vacuum chamber;
the scanning magnetron device as described above;
a planar target in the vacuum chamber; and
a pedestal configured to support a substrate in the vacuum chamber.

Additional aspects and advantages of the present invention will be set forth in part in the following description, some of which will be apparent from the following description, or will be learned by practice of the present invention.

### BRIEF DESCRIPTION OF THE DRAWINGS

The present invention is further described below with reference to the accompanying drawings and embodiments, in which:

FIG. 1 is a schematic diagram of a typical prior art magnetron sputtering apparatus;

FIG. 2 is a schematic diagram of a prior art magnetron ;

FIG. 3 is a schematic diagram of a prior art magnetron ;

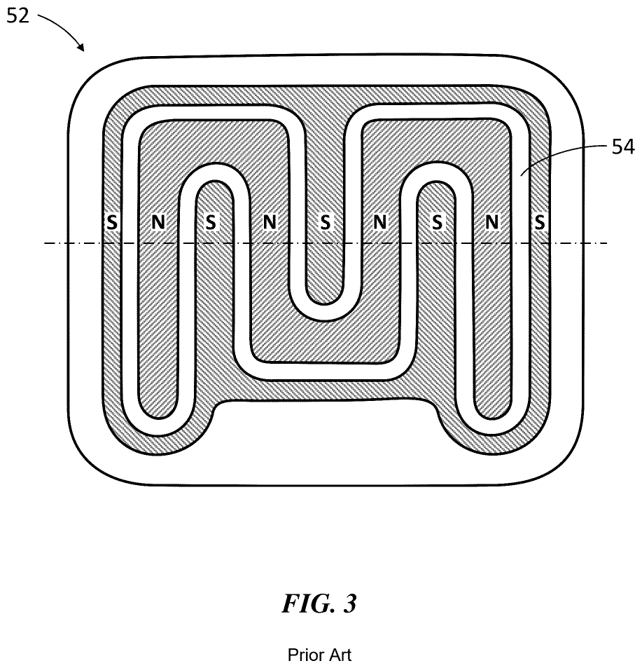

FIG. 4 is a schematic diagram of a prior art magnetron;

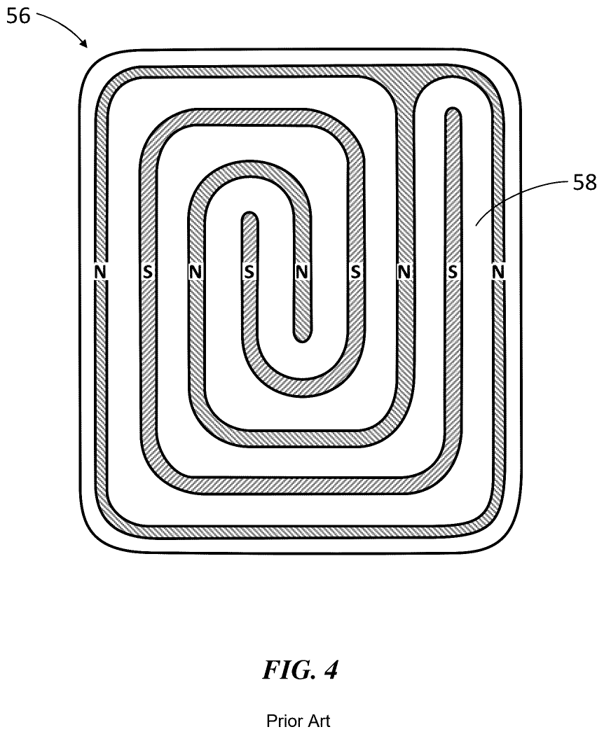

FIG. 5 is a schematic diagram explaining the transformation of a rotating target and a corresponding magnetron into a planar target and a planar magnetron;

FIG. 6 is a schematic diagram of a magnetron scanning along a first direction and a second direction according to an embodiment of the present invention;

FIG. 7 is a diagram showing a relationship between the normalized target erosion depth at a location on a target and the distance of that location from the target edge, for a series of scanning distances of a magnetron along a first direction according to an embodiment of the present invention;

FIG. 8 is a graph showing a relationship between the length of plasma passing through a location within unit size of the planar sputter target when scanning along the first direction, and, the distance of that location from an edge of the planar target, for a series of scanning distances of a magnetron along a second direction according to an embodiment of the present invention;

FIG. 9 is a schematic diagram of a magnetron according to an embodiment of the present invention;

FIG. 10 is a schematic diagram of an outer magnet assembly in FIG. 9;

FIG. 11 is a schematic diagram of an inner magnet assembly in FIG. 9;

FIG. 12 is a cross-sectional view along A-A in FIG. 9;

FIG. 13 is a schematic diagram of the magnetic field lines into a sputter target produced by an inner magnet, an outer magnet and a middle magnet in FIG. 12;

FIG. 14 is a diagram showing a relationship between the normalized depth of the deepest erosion groove on a target and a weakening factor of a magnetic field strength generated into a sputter target by a semicircular section, for a series of scanning distances of a magnetron in a second direction, according to an embodiment of the present invention; and

FIG. 15 is a schematic diagram of a magnetron according to another embodiment of the present invention.

### REFERENCE NUMERALS LIST

20: planar target sputtering apparatus,
22: vacuum chamber,
24: pedestal,
26: substrate,
28: planar target,
30: insulating plate,
32: backing plate,
34: back chamber,
36: insulating plate,
38: plasma,
40: linear magnetron,
42: inner magnetic pole,
44: outer magnetic pole,
46: gap,
48: outer linear portion,
50: outer semicircular portion,
52: magnetron,
54: plasma closed loop,
56: magnetron,
58: plasma closed loop,
60: magnetron,
70: outer magnetic pole,
72: outer linear portion,
74: outer semicircular portion,
76: outer magnet,
78: outer magnet,
80: inner magnetic pole,
82: inner linear portion,
84: inner semicircular portion,
86: inner magnet,
88: inner magnet,
90: middle magnetic pole,
92: middle magnet,
94: middle magnet,
100: linear section,
110: semicircular section,
120: magnetron of multi-linear portions,
130: outer magnetic pole of multi-linear portions,
132: first connecting unit,
134: a plurality of outer linear portions,
136: outermost linear portion,
138: a plurality of outer semicircular portions,
140: inner magnetic pole of multi-linear portions,
142: second connecting unit, and
144: a plurality of inner linear portions.

### DETAILED DESCRIPTION

Several embodiments of the present invention will be described in detail below. The embodiments are illustrated in conjunction with the drawings, where the same or similar reference numerals indicate the same or similar elements or elements having the same or similar functions throughout. The embodiments described below with reference to the accompanying drawings are illustrative only for the purpose of explaining the present invention, and are not to be construed as limiting the present invention.

In the description of the present invention, it should be understood that directions involved are merely intended to facilitate the description of the present invention rather than indicate or imply that the indicated apparatus or element must have a specific direction and must be configured and operated according to the specific direction. Therefore, these directions should not be construed as limiting the present invention.

In the description of the present invention, “a plurality of” means more than two, the description of “first” and “second” is merely for the purpose of distinguishing technical features, but shall not be understood as an indication or implication of relative importance, or an implicit indication of a quantity of indicated technical features, or an implicit indication of the sequence of the indicated technical features.

In the description of the present invention, unless otherwise explicitly defined, terms such as “arrange”, “connect” and the like should be understood in a broad sense, and those skilled in the art can reasonably determine the specific meanings of the above terms in the present invention in conjunction with the specific contents of the technical solutions.

In the description of the present invention, the description with reference to the terms “one embodiment”, “some embodiments” or the like means the particular features, structures, materials or characteristics described in combination with the embodiment or example are included in at least one embodiment or example of the present invention. In this specification, the above terms do not necessarily refer to the same embodiments or examples. Furthermore, the specific features, structures, materials, or characteristics described can be combined in any suitable manner in any one or more embodiments or examples.

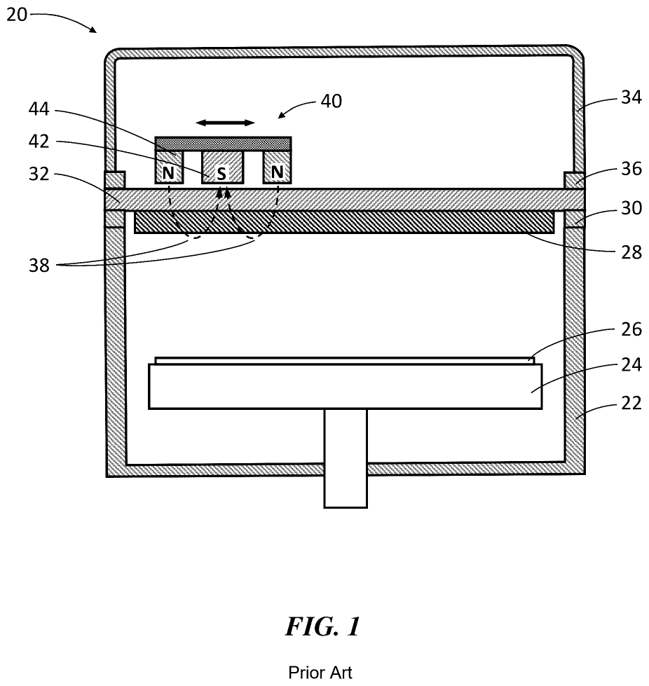

For convenience of understanding, the general principle of magnetron sputtering will be described in conjunction with FIG. 1. During sputtering, argon gas flows into a vacuum chamber. The linear magnetron 40 generates a magnetic field. The negatively biased planar target 28 generates an electric field. Electrons move from the planar target 28 to a substrate 26 under the electric field. During the movement, the electrons collide with argon atoms to ionize the argon atoms to generate argon ions and new electrons. The argon ions are accelerated as attracted by the electric field towards the planar target 28 to bombard the target surface to sputter atoms from the target 28. The sputtered atoms from the target 28 are deposited onto the surface of the substrate 26 such that a film forms on the substrate thereto. The secondary electrons generated during sputtering help maintain a plasma 38 across the surface of the target 28. Thereby, the Ar atom ionization and bombardment of argon ions as described above go on and on, and the deposition of a thin film by means of magnetron sputtering is performed successfully.

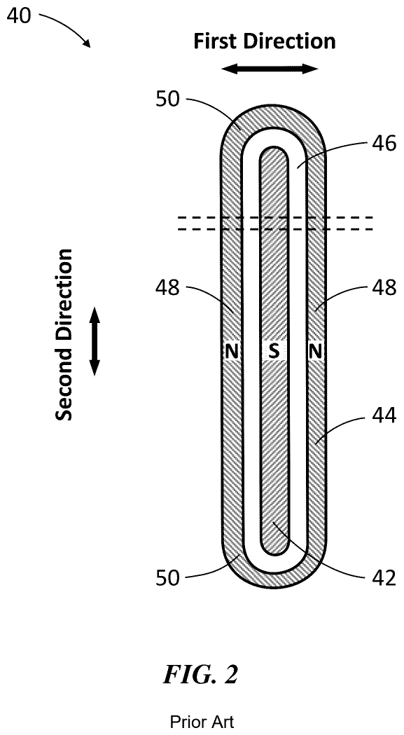

Referring to FIG. 2, when the magnetic field strength of the inner magnetic pole 42 is nearly the same as that of the outer magnetic pole 44, the magnetic field strength at a center line of the gap 46 is the strongest in its component parallel to target surface, and therefore the density of the plasma formed accordingly is the highest at a center line of the gap 46. The distribution of the actual plasma density is generally a normal distribution with the center line of the gap as a symmetry line. That is, the plasma density is the highest along the center line, and gradually lowers towards both sides. For simplicity, the plasma is simply represented by a line at the highest density, and the plasma looks like a racetrack-type closed loop under this simplified representation.

As shown in FIG. 2, the magnetron is then divided into a plurality of equal units along a linear direction (which is denoted herein as a second direction), where one of the units is defined by two dashed lines as shown. In a linear section of the plasma corresponding to the outer linear portion and inner linear portion of the magnetron, the plasma within each unit is parallel to a linear direction. The length of the plasma included in each unit of the linear portion is defined as 1 unit length, which actually includes a sum of the lengths of a unit of plasma on a left side and a unit of plasma on a right side. However, in the semicircular section of the plasma corresponding to the outer semicircular portion 50 shown in FIG. 2, the length of plasma in each unit increases significantly, approaching ˜5 units at a vertex of the semicircular section. The plasma at the vertex of the semicircular section is substantially parallel to a scanning direction of the magnetron, which is denoted herein as a first direction. When the magnetron scans along the first direction, for the linear portion 48 of the plasma, the length of plasma passing through per unit size of the sputter target during a unit time is relatively short since the length of plasma is relatively short and plasma is perpendicular to a scanning direction, thus the amount of erosion on the corresponding area of the target surface is relatively small. In contrast, for the outer semicircular portion 50 of the plasma, since the length of the plasma is long, and an included angle exists between a tangent line of the plasma and the scanning direction, the included angle gradually decreases from a beginning part of the semicircular section to the vertex, the length of the plasma passing through per unit size of the sputter target during a unit time is relatively long, the amount of erosion on the corresponding area of the target surface is relatively heavy. The closer the position is to the vertex of the semicircular portion, the greater the amount of erosion at the position becomes. This will cause an amount of erosion of the target material corresponding to the semicircular portion to be greater than an amount of erosion corresponding to the linear portion. When the target material corresponding to the semicircular portion is eroded through, the planar target 28 cannot be used any more. In this case, there are still a lot of materials that are not eroded in other parts of the target and, consequently, the planar target utilization is not high.

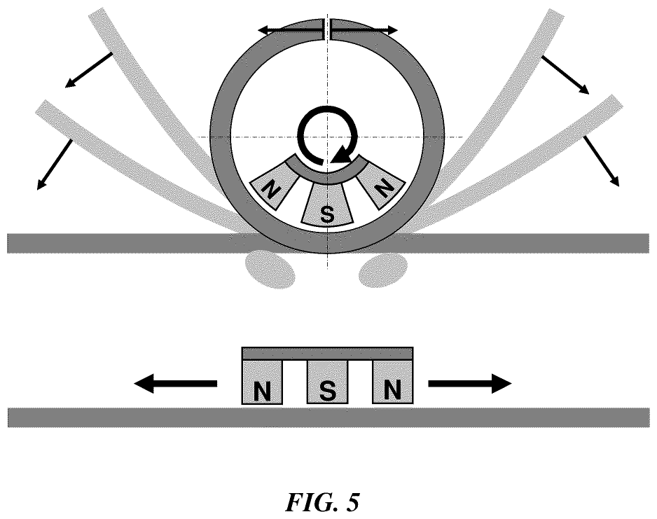

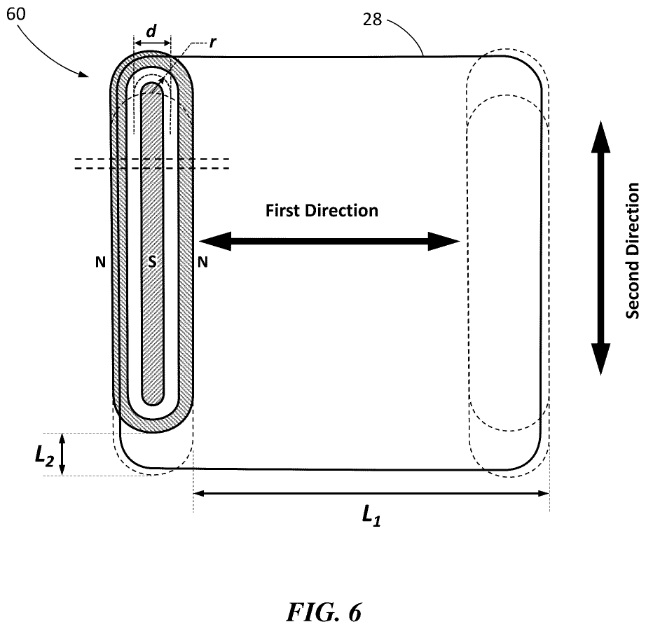

The magnetron 60 shown in FIG. 6 according to an embodiment of the present invention can be applied to the magnetron device described above. The magnetron 60 is also an elongated and linear magnetron, and can scan along the first and second directions relative to a sputter target to achieve uniform erosion of the planar target 28 and relatively high target material utilization. The magnetron sputtering of a rotary target is widely used because the target material utilization of the rotating target is relatively high, generally greater than 70%. It would be helpful to compare rotating target magnetron sputtering and planar target magnetron sputtering when considering how to improve planar target utilization. As shown in FIG. 5, the slitting and unfolding of a regular rotary target into a planar target and the flattening a corresponding magnetron are illustrated: a circular-tube-shaped rotary target is cut from the center of an upper surface, along a direction parallel to a rotation axis of the rotary target; and the rotary target is then flattened into a planar rectangular target. A magnetron suitable for a rotary target is similar to that shown in FIG. 2, and a linear portion with uniform magnetic field strength is relatively long, close to a length of a planar rectangular sputter target. Since the rotary target is kept rotating during magnetron sputtering, a long section in the middle of the rotary target can be eroded uniformly. Only the two ends of the rotary target material corresponding to the semicircular sections at the two ends of the magnetron are eroded deeper, as compared to the middle part, i.e., the linear section. Referring to FIG. 5, when the rectangular planar target has the same length as the rotary target, a width of the rectangular planar target is the same as or greater than the perimeter of the rotary target, and a magnetron used for the planar target is similar to the magnetron used in rotary target sputtering apparatus, the target material utilization of the planar target should be similar to the high utilization of the rotary target, i.e., 70% or higher. However, the rotary target is continuously rotating, and the magnetron on the planar target is scanning back and forth, such that the edge of the planar target is less eroded than the middle portion of the target, and the edge of the planar target is hardly eroded. On this basis, the target material utilization of the planar target will be slightly lower than that of a rotating target.

In summary, the length of the planar rectangular target can be similar to the length of the race-track magnetron, and the effect of the width of the planar target on the target material utilization is closely related to the width of the magnetron. In the case where the width of the planar target is very close to that of the magnetron, then the magnetron is not allowed to move, thus, the target material utilization is very low. In the case where the planar target is much wider than the magnetron, then the magnetron is allowed to scan back and forth along the first direction, the target material utilization can be increased significantly. In summary, referring to FIG. 6, the length of the planar rectangular target 28, i.e., a dimension of the planar target along the second direction, can be similar to the length of the magnetron 60, and the effect of the width of the planar target 28 on the target material utilization is closely related to the ratio of target width to the width of the magnetron 60. In the case where the width of the planar target 28 is very close to that of the magnetron 60, then the magnetron 60 is not allowed to move, thus, the target material utilization is very low. In the case where the planar target 28 is much wider than the magnetron 60, then the magnetron 60 is allowed to scan back and forth along the first direction, the target material utilization can be increased significantly.

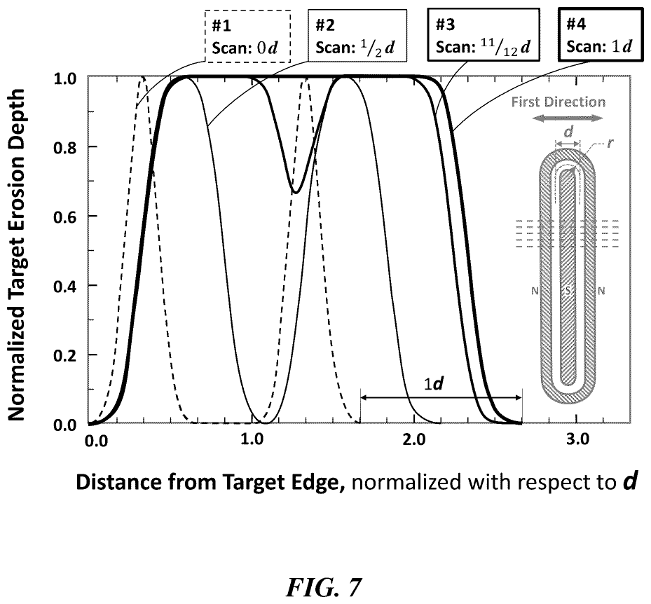

The principle of scanning of the magnetron along the first direction to improve the target material utilization has been briefly described above. Subsequently, as will be described in greater detail below, the distance L₁ which the magnetron scans along the first direction in this embodiment satisfies: L₁≥d, where d represents a distance between the center lines of the gaps 46 on two sides of the linear magnetron in FIG. 6. Referring to FIG. 7, the Y-axis represents an erosion depth at a location on a target, in which the erosion depth at the deepest part is normalized to 1 for the convenience of description. The X-axis represents the distance of that location from the target edge along the first direction, in which the distance d between the center lines of the gaps on two sides in FIG. 6 is normalized to 1. Curves #1 to #4 are erosion profiles, i.e., erosion depth versus a location on the planar target along the first direction, corresponding to a series of scanning distance of the magnetron along the first direction according to an embodiment of the present invention: Curve #1 corresponds to no scanning along the first direction, Curve #2 corresponds to scanning with a distance of ½d along the second direction, Curve #3 corresponds to scanning with a distance of 11/12d along the first direction, and Curve #4 corresponds to scanning with a distance of 1d along the first direction.

It can be seen from Curve #1 in FIG. 7 that, before the magnetron 60 starts scanning, the left and right peaks of the erosion depth of the target material correspond to a center line of a left gap 46 and a center line of a right gap 46, respectively, i.e., the locations where the plasma density is the highest. The distance between the left and right peaks is denoted as d, the total erosion width is denoted as 1⅔d, and an area with a width of ⅓d in the middle (corresponding to a location directly above the inner magnetic pole) does not have any erosion. It can be seen from Curve #2 that the magnetron 60 scans with a distance of ½d along the first direction, which is half the distance between the two erosion peaks at the starting position. The area with a width of ⅓d having no erosion in Curve #1 begins to disappear, and the total width of eroded area increases to 2⅙d, which equals the total of the original width, 1⅔d, of eroded area and the scanning distance of ½d. It can be seen from Curve #3 that the magnetron 60 scans with a distance of 11/12d along the first direction, the erosion in the middle area is more uniform, and only a very narrow segment in the middle is eroded slightly shallower than the deepest erosion groove. It can be seen from Curve #4 that the magnetron scans with a distance of d along the first direction, the total erosion width increases to 2⅔d, the erosion in the middle segment is very uniform and becomes the deepest, only the edge areas at the two ends have a shallow erosion depth, and there is almost no erosion at two ends. From the perspective of target material utilization, this erosion depth distribution shown by Curve #4 is ideal. In summary, the uniform erosion of the target material in the middle segment can be achieved, as long as the magnetron 60 scans with at least the distance between the center lines of the gaps on two sides of the magnetron along the first direction.

As discussed above, the magnetron 60 improves the non-uniform erosion of the planar target 28 along the first direction by scanning along the first direction. However, for the racetrack-type magnetron with an arc, or semicircular, end part, when the magnetron 60 scans along the first direction, the semicircular section of the magnetron forms a deep erosion groove at the corresponding position of the target. That is, the scanning of the magnetron 60 along the first direction increases the non-uniform erosion of the planar target 28 along the second direction. On this basis, the dashed lines in the FIG. 6 represent the magnetron 60 scanning to different positions along both the first direction and the second direction. The magnetron of this embodiment can also be moved by the driving device along the second direction to further achieve more uniform erosion of the planar target 28 along the second direction, and the reason is as follows. In case the magnetron 60 is not moved along the second direction and it scans only along the first direction, the vertex portion of the semicircular section 110 with the deepest erosion always moves along a straight line parallel to the first direction, so as to form a deep erosion groove in the corresponding area of the planar target 28. When the magnetron 60 scans along the second direction, the vertex portion of the semicircular section 110 with the deepest erosion does not move along a straight line, such that the maximum depth of the erosion groove on the corresponding area decreases. Therefore, the erosion is more uniform, and the uniform erosion of the target can be further achieved in conjunction with the differential setting of the magnetic field strength generated on the target sputter surface area between the semicircular section 110 and the linear section 100.

It should be noted that, if the magnetron 60 does not scan along the second direction, in order to ensure the full-face erosion of the target material along the second direction, the dimension of the magnetron 60 along the second direction (defined as a length of the magnetron 60 for convenience of illustration) can be equal to or slightly greater than the dimension of the planar target 28 along the second direction (defined as the length of the planar target 28 for convenience of illustration). That is, the outer perimeter of the magnetron 60 can extend beyond a certain distance relative to the edge of the planar target 28 along the second direction, the sputtering can be properly performed by the magnetron within this distance; and if the magnetron 60 scans beyond this distance, the magnetron 60 cannot confine electrons to the surface of the planar target 28, and plasma cannot be effectively sustained and interruption of sputtering will occur. The distance beyond the edge of the planar target varies depending on the planar target 28 thickness and the magnetron 60, but is usually small relative to target thickness. On this basis, if the magnetron 60 scans along the second direction, the length of the magnetron 60 needs to be less than the length of the planar target 28, such that the magnetron 60 has enough moving space along the second direction to maintain the plasma and the sputtering process. It can be understood that the longer the distance that the magnetron 60 scans along the second direction, the shorter the length of the magnetron 60.

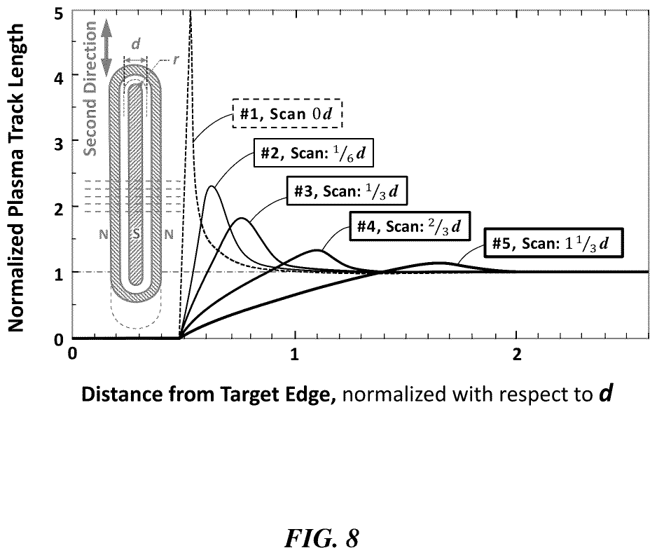

Referring to FIG. 8, which shows the relationship between the length of plasma passing through a location within unit size of the sputter target when scanning along the first direction and the distance of that location from the edge of the planar target 28, for a series of scanning distances of the magnetron 60 along the second direction. The longer the length of the plasma swept the target surface, the heavier the erosion and the deeper the erosion depth. It is assumed that the magnetic field strength of the linear section 100 is the same as that of the semicircular section 110 in the FIG. 8. The Y-axis in the figure represents the length of the plasma swept a location within the unit size along the first direction. For the convenience of illustration, when the magnetron 60 scans along the first direction, the length of the plasma sweeping across a location on the planar target 28 in the unit size by the linear section 100 of the magnetron is normalized to 1. The X-axis represents a distance of the location from the edge of the target, where the edge is parallel to the first direction. Curves #1 to #5 are curves corresponding to a series of scanning distances of magnetron 60. Curve #1 corresponds to no scanning along the second direction. Curve #2 corresponds to a scanning distance of ⅙d along the second direction. Curve #3 corresponds to a scanning distance of ⅓d along the second direction. Curve #4 corresponds to a scanning distance of ⅔d along the second direction. Curve #5 corresponds to a scanning distance of 1⅓d along the second direction.

As shown in Curve #1 in FIG. 8, when the magnetron 60 does not scan along the second direction, the peak of Curve #1 is the highest (the peak is near the Y-axis value of 5) among all the curves. As described above, this also means that when the magnetron 60 is scanning along the first direction, the length of the plasma scanned within the unit size at a position corresponding to the peak on the planar target 28 is the longest, and thus the corresponding erosion groove is the deepest. Then the peak value in Curve #1 decays to 1 in a very short distance from the target edge along the second direction. This indicates a non-uniform erosion on the target surface. It can be seen in conjunction with Curve #2 that when the magnetron 60 scans with a distance of ⅙d along the second direction, the peak of the Curve decreases significantly (the peak is near the Y-axis value of 2), the erosion depth at a position on the planar target 28 corresponding to the peak decreases significantly, and transitions smoothly to the value of 1, and this indicates that the erosion is relatively uniform in such a case.

It should be noted that, the longer the magnetron 60 scans along the second direction, the shallower the erosion depth at the position corresponding to the peak on the planar target 28. It can be seen from FIG. 8 that as the scanning distance along the second direction increases, the height of the peak representing the maximum erosion depth will also decrease accordingly, which is advantageous for the erosion uniformity of the planar target 28. However, the magnetron 60 shall be prevented from scanning a certain distance beyond the edge of the planar target 28 in order to maintain a stable plasma. The longer the distance the magnetron 60 that scans along the second direction, the shorter the linear magnetron 60 needs to be, and the shorter the total time that an end part area of the planar target 28 along the second direction is effectively eroded, thus resulting in an insufficient erosion on the end part area.

As shown in FIG. 8, among the curves representing the scanning distance of the magnetron 60 along the second direction, the curves each have a rising section rising from a position lower than the Y-axis value of 1 to a peak, which represents that, in a range extending from the edge of the target toward the center of the planar target 28, the length of the plasma sweeping across the planar target 28 within the unit size by the semicircular section 110 is smaller than the length of the plasma corresponding to the linear section 100, this also causes the non-uniform erosion. In such a case, the longer the scanning distance along the second direction is, the larger the range of low erosion near the target edge is. In summary, the following conclusion can be drawn: the maximum erosion depth of the planar target 28 along the second direction gradually decreases with the increase of the scanning distance of the magnetron 60 along the second direction. However, the area of insufficient erosion in the edge area of the target gradually increases. In view of this, according to an embodiment, the distance L₂ with which the magnetron 60 scans along the second direction (as shown in FIG. 6) is further limited. When the magnetron 60 scans within a selected range, both the maximum erosion depth formed on the planar target 28 by the semicircular section 110 and the range of the area of insufficient erosion can be considered, the utilization of the planar target 28 can be improved. In some implementations, the scanning distance L₂ of the magnetron 60 along the second direction satisfies: 0.5d≤L₂≤2d.

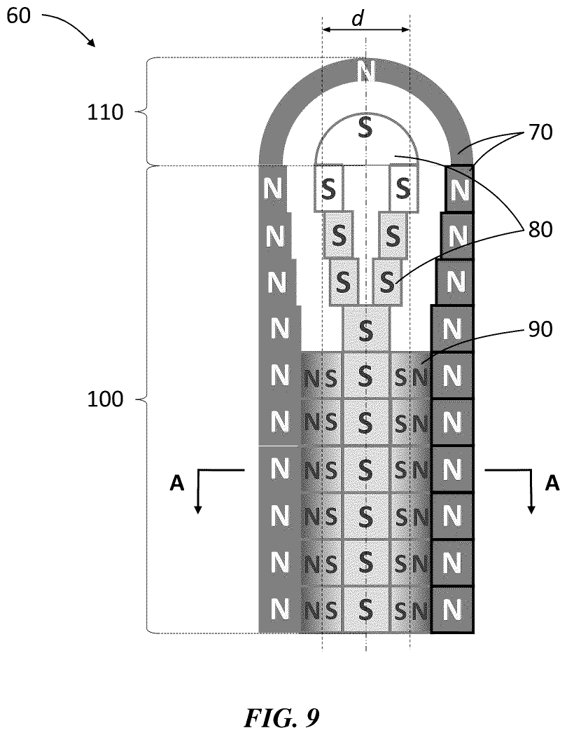

It can be seen from the foregoing description that the magnetron reciprocates along the first direction and the second direction for a certain distance to improve the erosion uniformity of each area of the planar target, such that the uniform erosion of the entire planar target is achieved, and the planar target utilization is improved. The specific structure of the magnetron in some embodiments of the present invention will be described in greater detail below. Referring to FIGS. 9 to 11, the magnetron device includes a magnetron 60 and a driving device. The magnetron 60 is configured to generate a magnetic field. The driving device is configured to drive the magnetron 60 to scan along the first direction and the second direction.

The magnetron 60 of this embodiment includes an outer magnetic pole 70 and an inner magnetic pole 80. The outer magnetic pole 70 is arranged around the outside of the inner magnetic pole 80. The outer magnetic pole 70 and inner magnetic pole 80 each include a plurality of magnets. The magnets in the outer magnetic pole 70 and the inner magnetic pole 80 are symmetrically distributed with a center line of the inner linear portion 82 as a symmetry axis.

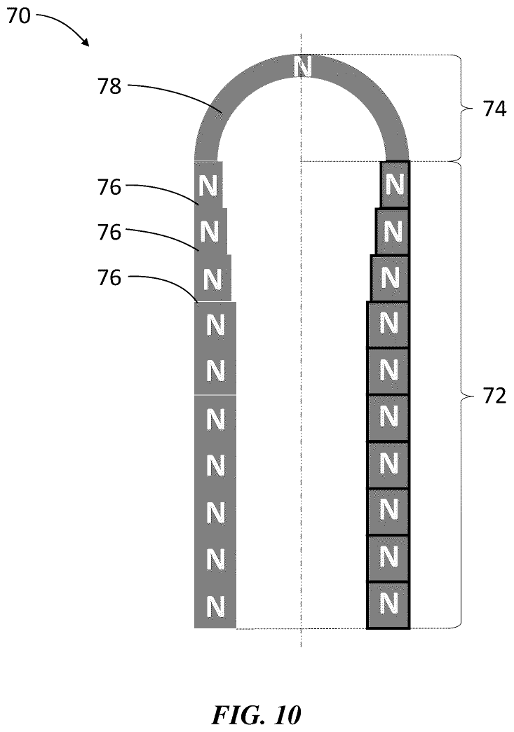

As shown in FIGS. 9 and 10, the outer magnetic pole 70 includes an outer linear portion 72 and an outer semicircular portion 74 connected to an end part of the outer linear portion 72. The outer linear portion 72 includes a plurality of outer magnets 76 at the end part of the outer liner portion 72. The plurality of outer magnets 76 are sequentially arranged along the second direction, i.e., magnetron linear direction. The outer semicircular portion 74 is configured in an arc-shaped structure. The outer semicircular portion 74 may include an integral arc-shaped outer magnet 78, or a plurality of outer magnets 78 distributed along an arc.

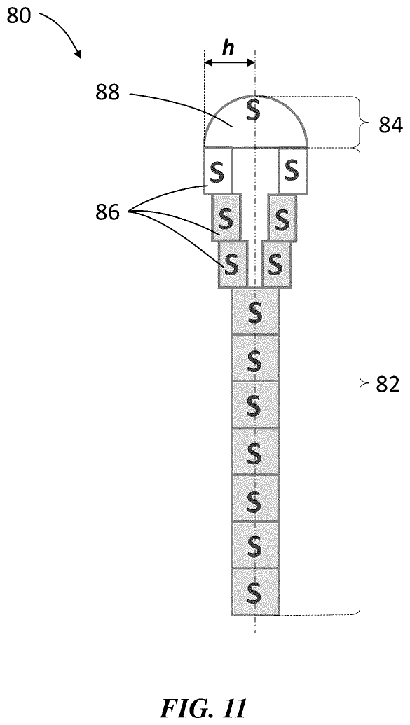

As shown in FIGS. 9 and 11, the inner magnetic pole 80 includes an inner linear portion 82. In some embodiments, the inner magnetic pole 80 further includes an inner semicircular portion 84. When the inner semicircular portion 84 is provided, the inner semicircular portion 84 is connected to an end part of the inner linear portion 82. The end part of the inner linear portion 82 includes a plurality of inner magnets 86, and the plurality of inner magnets 86 are sequentially arranged along the second direction. The inner semicircular portion 84 is configured in an arc-shaped structure. The inner semicircular portion 84 may include an integral arc-shaped inner magnet 88, or a plurality of inner magnets 88 distributed along an arc.

The two outer linear portions 72 are arranged in parallel, the two outer linear portions 72 are arranged on opposite sides of the inner linear portion 82 in parallel, the outer linear portions 72 and the inner linear portion 82 are arranged to form a gap between the outer linear portion and inner linear portion. In the illustrated embodiment, the two outer linear portions 72 are arranged symmetrically relative to the inner linear portion 82. Two ends of the outer semicircular portion 74 are connected to the corresponding ends of the two outer linear portions 72, respectively.

The outer linear portion 72 of the outer magnetic pole 70 and the inner linear portion 82 of the inner magnetic pole 80 form a linear section 100. The outer semicircular portion 74 and the inner semicircular portion 84 together form a semicircular section 110. It should be noted that, in some embodiments, the linear section 100 includes two outer linear portions 72 and inner linear portion 82, and the semicircular sections 110 are connected to opposite ends of the linear section 100. Thereby, a racetrack-type magnetron is formed. In some other embodiments, the linear section 100 may also include more outer linear portions 72 which are parallel to each other and form a wider magnetron, which will be described later in other embodiments.

In some embodiments, the magnetron 60 further enables erosion at rounded corners of the planar target 28 to further enhance utilization of the planar target 28. The magnetron 60 has a first scanning limit position along the first direction, and a second scanning limit position along the second direction. In particular, as shown in FIG. 6, the first scanning limit position includes a leftmost position and a rightmost position, and the second scanning limit position includes an uppermost position and a lowermost position.

When the magnetron 60 is positioned at the first scanning limit position or the second scanning limit position, the semicircular section 110 of the magnetron 60 is concentrically arranged with the corresponding rounded corner of the planar target 28. For example, when the magnetron 60 is at an upper left position in the FIG. 6, the semicircular section 110 is concentrically arranged with the rounded corner at the upper left corner of the planar target 28. In another example, when the magnetron 60 is at the lower right position, the semicircular section 110 is concentrically arranged with the rounded corner at the lower right corner of the planar target 28, such that the plasma 38 corresponding to the semicircular section 110 can be distributed approximately along the contour of the rounded corner. Thereby, the full-face erosion at the rounded corner is achieved. Further, the full-face erosion of the entire planar target 28 is achieved. The inefficiency of the erosion at the rounded corner of the planar target by a regular magnetron is effectively tackled by the present invention.

In some embodiments, referring to FIG. 6, when the magnetron 60 is positioned at the first scanning limit position or the second scanning limit position, an outer edge of the magnetron 60 will extend beyond the outer edge of the planar target 28. As described above, the plasma density is distributed in a regular manner, approximately in a normal distribution with the center line of the gap between the inner magnetic pole and outer magnetic pole as a symmetry line, the plasma density is highest at the center line. In the case where the outer edge of the magnetron 60 extends beyond the planar target 28, the magnetron gap centerline with stronger erosion capability can be closer to the edge of the planar target 28, so as to increase the erosion of the edge area of the planar target 28. In conjunction with the foregoing, the semicircular section 110 at the scanning limit position is arranged to be concentric with the rounded corner of the target, so as to erode the rounded corner of the target more effectively. It should be noted that the length of the magnetron 60 that extends beyond the outer edge of the planar target 28 should not affect the continuous operation of magnetron sputtering. In some embodiments, the length of the part of the outer edge of the magnetron 60 that extends beyond the outer edge of the planar target 28 is not greater than 15 mm.

In some embodiments, the magnetic field strength of the inner magnetic pole 80 is greater than that of the outer magnetic pole 70. In some implementations, the magnetic field strength of the inner linear portion 82 is greater than that of the outer linear portion 72, and when the inner magnetic pole 80 has an inner semicircular portion 84, the magnetic field strength of the inner semicircular portion 84 is greater than that of the outer semicircular portion 74. The plasma density follows a normal distribution with the centerline of the gap between the inner and outer magnetic poles as a symmetry axis on the premise that the magnetic field strengths of the inner and outer magnetic poles are equal. If the magnetic field strength of the inner magnetic pole 80 is greater than that of the outer magnetic pole 70, the position where the plasma density is highest will be shifted outward from the center line of the gap, such that when the magnetron is at the first scanning limit position and the second scanning limit position, the outer edge of the magnetron 60 can meet the requirement of full-face erosion even if the outer edge of the magnetron does not extend beyond the outer edge of the planar target 28, or the length of the part of the outer edge of the magnetron 60 that extends beyond the out edge of the planar target 28 decreases.

In some embodiments, in order to solve the issue of the excessive erosion at the arc end, or the semicircular section, of the magnetron on the planar target, some magnetron designers and manufacturers weaken directly the magnetic field strength of the semicircular section. In this way, the plasma density is reduced, such that the erosion of the target material by the semicircular section is reduced. However, since the erosion of the semicircular section is significantly stronger than that of the linear portion, the magnetic field strength of the semicircular section needs to be greatly reduced, which in turn affects the igniting and sustaining of the plasma. In view of this, according to an embodiment, a scanning magnetron device is provided. The scanning magnetron device can improve the non-uniformity erosion of the planar target 28 in the second direction without affecting the igniting and sustaining of the plasma.

Referring to FIG. 9, the magnetron according to an embodiment further includes a middle magnetic pole 90. The middle magnetic pole 90 includes a middle linear portion arranged in a gap between the outer linear portion 72 and the inner linear portion 82 for enhancing the magnetic field strength of the linear section of the magnetron 60. The middle linear portion further includes a plurality of magnets. The plurality of magnets of the middle linear portion are symmetrically distributed with the center line of the inner linear portion 82 as a symmetrical axis. For convenience of illustration, the magnet included in the middle magnetic pole 90 is called a middle magnet.

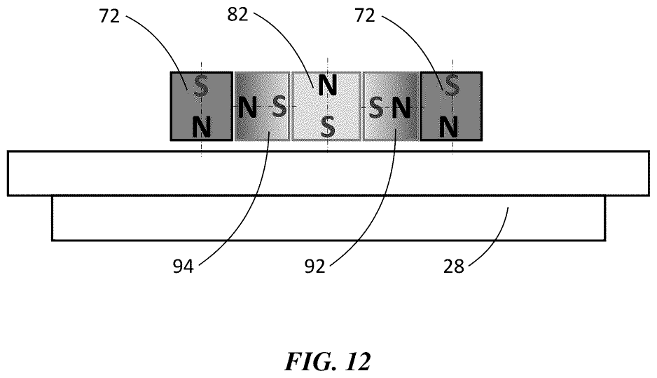

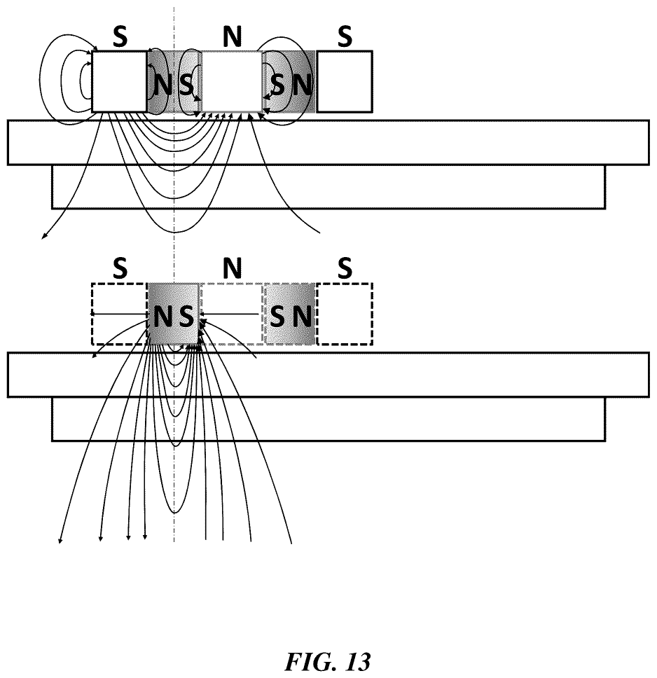

In the embodiment shown in FIG. 9, a linear section 100 is formed by the outer linear portion 72 of the outer magnetic pole 70, the inner linear portion 82 of the inner magnetic pole 80, and the middle linear portion of the middle magnetic pole 90. In some embodiments, a semicircular section 110 is formed by the outer semicircular portion 74 and the inner semicircular portion 84 together. Referring to FIGS. 12 and 13, both the connecting lines of the two opposite N-and S-magnetic poles of the outer linear portion 72 and the inner linear portion 82 are perpendicular to the target surface to be sputtered. The outer magnetic pole and the inner magnetic pole have opposite polarities facing the planar target. In some implementations, the S pole of the inner magnet portion 82 faces the planar target 28, the N pole thereof faces away from the planar target 28; the N pole of the outer magnet portion 72 faces the planar target 28, the S pole thereof faces away from the planar target 28. The connecting lines of the inner and outer magnetic poles are arranged to be along a vertical direction shown in FIGS. 12 and 13. For the middle magnetic pole 90 shown in FIGS. 9, 12 and 13, the respective connecting lines of the magnetic poles of the middle magnets 92 and 94 are arranged to be parallel to the target surface to be sputtered, i.e., in a horizontal direction shown in FIG. 13, and the two magnetic poles of the middle magnet 92 face the outer linear portion 72 and the inner linear portion 82, respectively. The magnetic poles of the middle magnets 92 and 94 at the outside are consistent with the magnetic poles of the outer magnet 72 facing the planar target 28, and the magnetic poles of the middle magnets 92 and 94 at the inside are consistent with the magnetic poles of the inner magnet 82 facing the planar target 28. In some implementations, one magnetic pole (for example, the N pole) of the middle magnet 92 faces the outer magnet 72, the other opposite magnetic pole (for example, the S pole) faces the inner magnet 82.

The magnetic field lines of the outer magnet 72, the inner magnet 82 and the middle magnets 92 and 94 are distributed as shown in FIG. 13. It can be seen from FIG. 13 that, the magnetic field of the outer magnets in the outer linear portion 72 and the inner magnets in the inner linear portion 82 have the strongest component parallel to the target surface at or near the center line of the gap. Similarly, the magnetic field of the middle magnet 92 has the strongest component parallel to the target surface at the center line of the gap, and thus the magnetic field strength of the linear section 100 can be increased after the superposition. As a result, the maximum magnetic field strength generated at target sputter surface by the linear section 100 is greater than that by the semicircular section 110. The difference between the amount of erosion of target material by the semicircular section 110 and the linear section 100 of magnetron 60 scanning in the first direction or scanning in both first and second directions can be reduced. The erosion corresponding to the linear section 100 is enhanced due to the enhancement of the magnetic field strength of the linear section 100. Therefore, in this embodiment, there is no need to reduce the magnetic field strength at the target sputter surface generated by the semicircular section 110, or the reduction amplitude can be lowered. Thereby, the plasma can be more easily ignited and sputtering processes can be done at a relatively low process pressure.

While it is described in the present invention that the maximum magnetic field strength is generated at target sputter surface by the linear section 100, it should not imply that the linear section 100 necessarily has a gradient of magnetic field change. In other words, the magnetic field strength of the linear section 100 can be uniform. For example, the magnetic field strength generated at target sputter surface by each portion of the linear section 100 along the second direction is the maximum magnetic field strength.

It has already been illustrated in conjunction with FIG. 8 how the scanning of magnetron 60 along the second direction improves the erosion uniformity in the case of uniform magnetic field strength. In the following, it will be illustrated how the scanning of magnetron 60 along the second direction reduces the need for the large difference in the magnetic field strength between the linear section 100 and the semicircular section 110 when the magnetic field strength between the linear section 100 and the semicircular section 110 is not uniform.

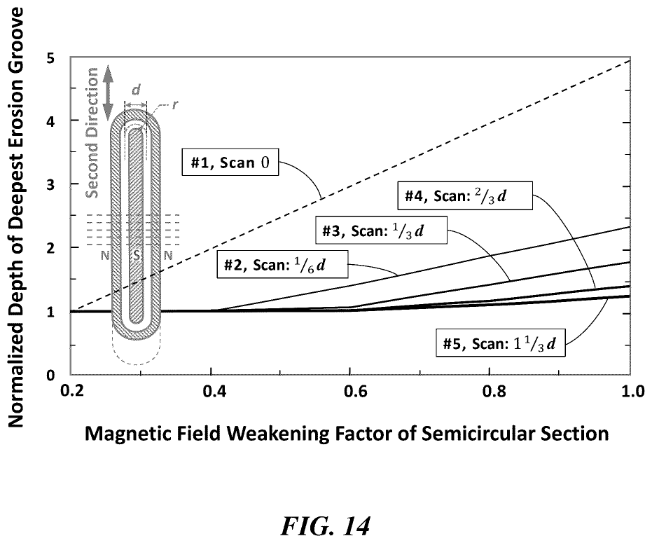

Referring to FIG. 14, which shows the relationship between the weakening factor of the magnetic field strength generated at target sputter surface by the semicircular section 110, and the erosion depth, for various scanning distances of the magnetron 60 along the second direction. In the figure, the Y-axis represents the maximum erosion depth of the target material, which is generally at a location corresponding to the semicircular section. For convenience of illustration, the depth of the erosion groove corresponding to the linear section 100 is normalized to 1. The depth of the erosion groove corresponding to the linear section 100 is relatively uniform, so that the curve (not shown in FIG. 14) corresponding to the linear section 100 is a horizontal line parallel to the X-axis and corresponding to the Y-axis value of 1. The X-axis represents a weakening factor of the magnetic field strength generated at target sputter surface by the semicircular section, and can be conversely understood as a strengthening factor of the magnetic field strength generated at target sputter surface by the linear section 100. If the magnetic field strength is not weakened, the corresponding X-axis value is 1, and correspondingly, an X-axis value of 0.8 means that the magnetic field strength generated at target sputter surface by the semicircular section 110 is weakened to 80%, and this is similar in the case of the other values. Curves #1 to #5 are curves corresponding to scanning distances of the magnetron 60 along the second direction. Curves #1, #2, #3, #4, and #5 correspond to no scanning, and scanning with a distance of ⅙d, ⅓d, ⅔d, 1⅓d, respectively, along the second direction. It should be noted that, in practice, the erosion depth of the planar target 28 is not strictly proportional to the magnetic field strength. For better understanding, the relationship between the erosion depth of the planar target 28 and the magnetic field strength is defined as a proportional relationship of 1:1.

It can be seen from the Curve #1 in FIG. 14 that, if the magnetron 60 does not scan along the second direction and the magnetic field strength is not weakened, the maximum erosion depth formed on the planar target 28 by the semicircular section 110 after the magnetron 60 scans along the first direction will be approximately 5 times the maximum erosion depth corresponding to the linear section 100, which will greatly affect the erosion uniformity of the target material. On the other hand, if the magnetron 60 does not scan along the second direction, when the magnetic field strength is weakened to about 20%, the maximum erosion depth corresponding to the semicircular section 110 is about the same as the maximum erosion depth corresponding to the linear section 100, but the magnetic field strength of the semicircular section 110 may be too weak to strike and sustain a plasma. It is understood that, from the perspective of the increase in the magnetic field strength of the linear section 100 instead of weakening the magnetic field strength of the semicircular section 110, Curve #1 represents that the magnetic field of the linear section 100 needs to be increased by about 5 times to cause approximately equal amount of erosion of the target material by the semicircular section 110, which will have relatively high demands on the linear section 100.

It can be seen in conjunction with the Curve #2 in FIG. 14 that, when the magnetron 60 scans along the second direction, even though the magnetic field strength of the semicircular section 110 is not weakened, the difference between the maximum erosion depths of the semicircular section 110 and the linear section 100 is significantly reduced. When the magnetic field strength of the semicircular section 110 is weakened, the difference between the maximum erosion depths of the semicircular section 110 and the linear section 100 is further reduced. For example, it can be seen from Curve #2, when the magnetic field strength is weakened to 40% (instead of 20% as the case of Curve #1), the maximum erosion depth corresponding to the semicircular section 110 is already approximately equal to the maximum erosion depth corresponding to the linear section 100.

Furthermore, it can be seen in conjunction with Curves #2 to #5 in FIG. 14 that, as the scanning distance of the magnetron 60 along the second direction increases, the weakening factor of the magnetic field strength of the semicircular section 110 can also decrease accordingly, or the degree of increasing the magnetic field strength of the linear section 100 can correspondingly decrease. In other words, when the magnetron 60 scans along the second direction, the magnetic field strength of the semicircular section 110 can be reduced to be within a range that does not affect the igniting and sustaining of the plasma, and the increase in the amplitude of the magnetic field strength of the linear section 100 can be reduced accordingly. Thereby, the requirement of strong magnetic field strength of the linear section 100 is loosened. Alternatively, it is not necessary to decrease the magnetic field strength of the semicircular section 110, and instead the difference between the maximum erosion depth of the semicircular section and the linear section is adjusted completely by increasing the magnetic field strength of the linear section 100. However, even in such a case, the requirement for an increased magnitude of magnetic field strength of the linear section 100 is also significantly reduced by scanning along the second direction, compared with the case in which the magnetron 60 does not scan along the second direction.

In some embodiments, referring to FIGS. 9 and 10, the end part of the outer linear portion 72 includes a plurality of sets of outer magnets 76. The magnetic field strength generated at target sputter surface by each set of outer magnets 76 decreases sequentially along a direction from the outer linear portion 72 to the outer semicircular portion 74 (e.g., from the bottom to the top in FIGS. 9 and 10), and the maximum magnetic field strength generated at target sputter surface by the outer semicircular portion 74 is not greater than the magnetic field strength generated at target sputter surface by the outermost set of outer magnets 76, such that abrupt changes in magnetic field strength from the linear section to semicircular section can be avoided. In addition, the magnetic fields generated at target sputter surface by adjacent magnets are superimposed to increase the magnetic field strength, and the foregoing setting can also prevent the superimposition of the outer semicircular portion 74 and the adjacent outer magnets 76 from excessively increasing the magnetic field strength. Thereby, the adverse effect on the differential setting of the magnetic field strength between the outer linear portion 72 and the outer semicircular portion 74 is avoided. It should be noted that the number of the outer magnets 76 included in each set is not limited in this embodiment, the number of the outer magnets 76 in different sets can be equal or different, and one set of the outer magnets 76 include at least one outer magnet 76. For example, as shown in FIGS. 9 and 10 the end part of the outer linear portion 72 includes three sets of the outer magnets 76, and each set includes one outer magnet 76.

In some embodiments, when the end part of the outer linear portion 72 includes a plurality of sets of outer magnets 76, the magnetic field strength generated at target sputter surface by the magnets can be adjusted by changing the magnetic field strength of the magnets themselves. For example, the cross-sectional area of each set of outer magnets 76 parallel to the target sputter surface decreases sequentially along a direction from the outer linear portion 72 to the outer semicircular portion 74. As a result, the magnetic field strength of each set of outer magnets 76 decreases sequentially and the overall magnetic field strength generated at target sputter surface decreases sequentially with other parameters kept consistent. As shown in FIGS. 9 and 10, the width of each set of outer magnets 76 decreases gradually, such that the cross-sectional area of each set of the outer magnets 76 decreases sequentially.

For another example, the height of each set of outer magnets 76 decreases sequentially along a direction from the outer linear portion 72 to the outer semicircular portion 74, such that the magnetic field strength of each set of outer magnets 76 decreases sequentially and the overall magnetic field strength generated at target sputter surface decreases sequentially with other parameters kept consistent.

For another example, each set of the outer magnets 76 is made of different materials with magnetic field strength weakened sequentially along a direction from the outer linear portion 72 to the outer semicircular portion 74, such that the magnetic field strength of each set of outer magnets 76 decreases sequentially and the overall magnetic field strength generated at target sputter surface decreases sequentially with other parameters kept consistent.

In some other embodiments, when the end part of the outer linear portion 72 includes a plurality of sets of outer magnets 76, the magnetic field strength generated at target sputter surface by the magnets can also be adjusted by changing the distance between the magnets and the target. In some implementations, the distance between each set of outer magnets 76 and the target material increases along a direction from the outer linear portion 72 to the outer semicircular portion 74, and the overall magnetic field strength generated at target sputter surface decreases sequentially even though the magnetic field strength of each set of outer magnets 76 is the same.

It should be noted that the above embodiments can be combined, for example, along the direction from the outer linear portion 72 to the outer semicircular portion 74, the magnetic field strength of each set of outer magnets 76 can decrease sequentially, and the distance between each set of outer magnets 76 and the planar target can increase sequentially.

When the end part of the outer linear portion 72 includes a plurality of sets of outer magnets 76 and the magnetic field strength generated at target sputter surface by each set of outer magnets 76 decreases sequentially, the peak value of the plasma density generated by each set of outer magnets 76 decreases gradually. As described above, the plasma density is normally distributed, the density is highest at the center line of the gap 46, and then gradually decreases along the first direction toward two sides of the center line. As the plasma density decreases at a location further away from the center line of the gap 46, and the erosion capability of plasma no longer meets the requirements for effective erosion, or full-face erosion. In other words, only the plasma extending within a certain range from the location with the highest density to two sides can effectively erode the planar target 28, and for the convenience of illustration, it is defined as an effective erosion area. If the peak value of the plasma density decreases, the width of the effective erosion area is also reduced. As a result, when the outer linear portion 72 scans to the scanning limit position along the first direction to reach the edge of the planar target 28 parallel to the second direction, a section of a target edge, which is the target edge area corresponding to magnetron end part with a plurality of sets of outer magnets 76, cannot be effectively eroded. On this basis, in some embodiments, referring to FIGS. 9 and 11, the end part of the inner linear portion 82 includes a plurality of sets of inner magnets 86 corresponding to the plurality of sets of outer magnets 76. The distances h between the end part of each set of inner magnets 86 facing the corresponding outer magnets 76 and the center line of the inner linear portion 82 increases sequentially along the direction from the outer linear portion 72 to the outer semicircular portion 74. As a result, the effective erosion area corresponding to the plurality of sets of outer magnets 76 can be shifted toward the outside. Thus, when the outer linear portion 72 scans to the scanning limit position along the first direction to reach the edge of the planar target 28, the entire edge area can be effectively eroded. Thereby, the full-face erosion of the planar target 28 is achieved.

It should be noted that the number of the inner magnets 86 included in each set is not limited in this embodiment. The number of the inner magnets 86 in different sets can be equal or different. One set of the inner magnets 86 include at least one inner magnet 86, for example, the end part of the inner linear portion 82 includes three sets of the inner magnets 86 as shown in FIGS. 9 and 11, and each set includes one inner magnet 86.

As an implementation of the foregoing embodiments, referring to FIGS. 9 to 11, the inner magnetic pole 60 further includes an inner semicircular portion 84, the inner semicircular portion 84 and the aforementioned outer semicircular portion 74 form a semicircular section 110. The inner semicircular portion 84 and the outer semicircular portion 74 are concentrically arranged.

Referring to FIG. 11, an end part (e.g., a top end in the figure) of the inner linear portion 82 facing the inner semicircular portion 84 includes two inner magnet arrays. The inner magnet arrays each include a plurality of sets of inner magnets 86, one end of each of the two inner magnet arrays is connected to a main segment of the inner linear portion 82, and the other end is connected to the inner semicircular portion 84. A distance between the two inner magnet arrays sequentially increases in a direction from the inner linear portion 82 to the inner semicircular portion 84, such that the end part of the inner linear portion 82 is in a gradually expanded state. Therefore, a distance h between the end part of each set of inner magnets 86 facing the corresponding outer magnet 76 and a center line of the inner linear portion 82 sequentially increases.

In some embodiments, referring to FIG. 10, the outside surfaces of the magnets in the outer semicircular portion 74 are aligned with each other. That is, the outside surfaces of each set of outer magnets 76 at the end part of the outer linear portion 72 are aligned with the outside surfaces of the outer magnets 78 in the outer semicircular portion 74. When the magnetic field strength of each set of outer magnets 76 at the end part is adjusted by reducing the width as shown in the figure, the effective erosion area can be moved towards the outside, so that the planar target 28 can be eroded in a full-face erosion manner when the outer linear portion 72 scans to the scanning limit position along the first direction to reach or even pass the edge of the planar target 28.

In some embodiments, referring to FIG. 9, the middle magnetic unit is shorter than the outer linear portion 72, such that the end part of the outer linear portion 72 can extend beyond the middle magnetic unit along the second direction. The portion that extends beyond the middle magnetic unit includes the plurality of sets of outer magnets 76 described above. Meanwhile, the magnetic field strength generated at target sputter surface by the outer semicircular portion 74 is not greater than that generated at target sputter surface by the outermost set of outer magnets 76, such that the middle portion of the linear section 100 exhibits a magnetic field, which gradually weakens from the end part and transitions to the semicircular section 110. As a result, the difference between the erosion capabilities of the linear section 100 and the semicircular section 110 is balanced, and any adverse effect on the plasma igniting and sustaining due to the decrease in the magnetic field strength of the outer semicircular portion 74 is prevented.

As described above, the semicircular section 110 has the strongest erosion capability during scanning, so as to form the deepest erosion groove. In view of this, in some embodiments, the magnetic field strength generated at target sputter surface by the semicircular section 110 can also be set to decrease gradually. Thereby, the difference in the erosion capabilities of different portions in the semicircular section 110 is reduced. In some implementations, the semicircular section 110 includes the outer semicircular portion 74 as discussed above, which is configured in the arc structure, and along the direction from the end part of the linear section to the vertex of the semicircular section 110. The outer semicircular portion 74 includes a plurality of sets of outer magnets which are not marked in FIG. 10, and the magnetic field strength generated at target sputter surface by the plurality of sets of outer magnets in the outer semicircular portion 74 decreases gradually one by one according to the order of arrangement of the sets of outer magnets. It should be noted that, in this embodiment, the number of the outer magnets included in each set in the outer semicircular portion 74 is not limited. The number of the outer magnets in different sets can be equal or different. Each set of outer magnets include at least one outer magnet.

In some embodiments, when the end part of the outer linear portion 72 and the outer semicircular portion 74 includes a plurality of sets of outer magnets, the magnetic field strength generated at target sputter surface by the magnets can be adjusted by changing the magnetic field strength of the magnets. For example, the cross-sectional area of each set of outer magnets 76 in the linear portion and the outer magnets in the semicircular portion parallel to the target sputter surface decreases gradually along a direction from the end part of the linear section to the vertex of the semicircular section 110, such that the magnetic field strength of each set of outer magnets 76 in the linear portion and the outer magnets in the semicircular portion decreases gradually and the magnetic field strength generated at target sputter surface decreases gradually with other parameters kept consistent. In some embodiments, the width of each set of outer magnets 76 in the linear portion and the outer magnets in the semicircular portion decreases gradually, such that the cross-sectional area of each set of the outer magnets 76 in the linear portion and the outer magnets in the semicircular portion decreases gradually from the first one of the sets of the outer magnets to the last one of the sets of the outer magnets.

For another example, the height of each set of outer magnets 76 in the linear portion and the outer magnets in the semicircular portion decreases gradually along a direction from the end part of the linear section 100 to the vertex of the semicircular section 110, such that the magnetic field strength of each set of outer magnets 76 in the linear portion and the outer magnets in the semicircular portion decreases gradually from one of the sets of the outer magnets to another and the magnetic field strength generated at target sputter surface decreases gradually from the first one of the sets of the outer magnets to the last one of the sets of the outer magnet with other parameters kept consistent.

For another example, each set of the outer magnets 76 in the linear portion and the outer magnets in the semicircular portion is made of different magnetic materials with magnetic field strength weakened gradually from the first one of the sets of the outer magnets to the last one of the sets of the outer magnet along a direction from the end part of the linear section 100 to the vertex of the semicircular section 110, such that the magnetic field strength of each set of outer magnets 76 in the linear portion and the outer magnets in the semicircular portion decreases gradually and the magnetic field strength generated at target sputter surface decreases sequentially with other parameters kept consistent.

In some other embodiments, when the end part of the outer linear portion 72 includes a plurality of sets of outer magnets 76 and the outer semicircular portion includes a plurality of sets of outer magnets, the magnetic field strength generated at target sputter surface by the magnets can also be adjusted by adjusting the distance between the magnets and the planar target. In an implementation, the distance between each set of outer magnets and the planar target increases gradually from the first one of the sets of the outer magnets to the last one of the sets of the outer magnet along a direction from the end part of the linear section 100 to the vertex of the semicircular section 110, and the magnetic field strength generated at target sputter surface decreases gradually from the first one of the sets of the outer magnets to the last one of the sets of the outer magnets.

It should be noted that the above embodiments can be combined, for example, along the direction from the end part of the linear section 100 to the vertex of the semicircular section 110, the magnetic field strength of each set of outer magnets 76 in the linear portion and the outer magnets in the semicircular portion can decrease gradually from the first one of the sets of the outer magnets to the last one of the sets of the outer magnet, and the distance between target sputter surface and each set of outer magnets 76 in the linear portion and the outer magnets in the semicircular portion can increase gradually from the first one of the sets of the outer magnets to the last one of the sets of the outer magnet.

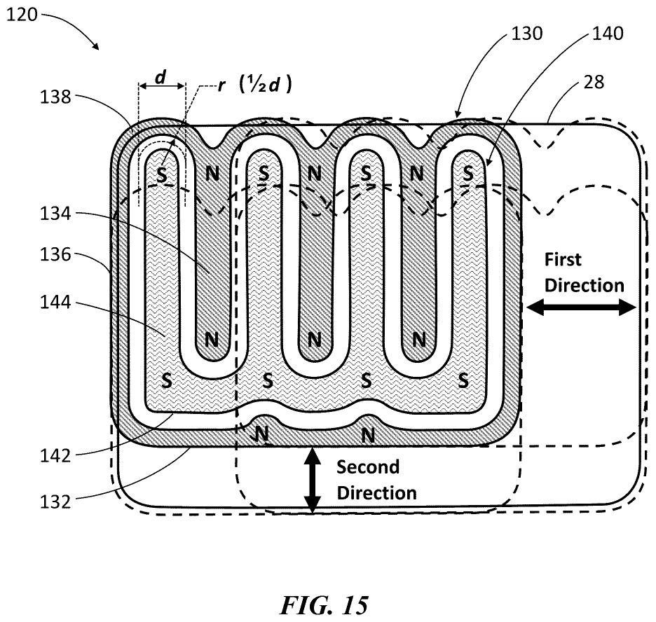

In some embodiments of a magnetron 120 of multi-linear portions, referring to FIG. 15, the outer magnetic pole 130 of the multi-linear portions includes a first connecting unit 132, a plurality of outer linear portions 134, two outermost linear portions 136 and a plurality of outer semicircular portions 138; the plurality of outer linear portions 134 are arranged at intervals along a first direction. As shown in the figure, two outermost linear portions 136 have a length slightly longer than that of the other plurality of outer linear portions 134. In this embodiment, the ends (e.g., upper ends) of the adjacent outer linear portions 134 are connected by the plurality of outer semicircular portions 138, and the other ends (e.g., lower ends) of the two outermost linear portions 136 are connected by the first connecting unit 132, so that the outer magnetic pole 130 of the multi-linear portions is closed.

The inner magnetic pole 140 of the multi-linear portions includes a second connecting unit 142 and a plurality of inner linear portions 144; the plurality of inner linear portions 144 are arranged at intervals along the first direction, the plurality of inner linear portions 144 and the plurality of outer linear portions 134 are alternately distributed, and the ends (for example, lower ends) of the adjacent inner linear portions 144 facing the first connecting unit 132 are connected by the second connecting unit 142.

In this embodiment, since the plurality of outer linear portions 134 and the plurality of inner linear portions 144 are provided, the width of the magnetron 120 along the first direction is increased, and the area of the magnetron covering the planar target 28 is increased, such that the scanning distance of the magnetron 120 along the first direction can be reduced. If the scanning frequency is kept constant, the speed of the magnetron can be reduced, the design requirement for the driving device can be reduced accordingly, and if the scanning speed is kept constant, the scanning frequency can be increased.

In this embodiment, the ends of the two outermost linear portions 136 are connected by the plurality of outer semicircular portions 138, and the other ends of the two outermost linear portions 136 are connected through the first connection unit 132. Two ends of the plurality of outer semicircular portions 138 and two ends of the first connecting unit 132 can be concentric with the rounded corner of the planar target 28 when the magnetron 120 is at the first scanning limit position and the second scanning limit position. Thereby, the full-face erosion of the rounded corner of the planar target 28 is achieved.

According to another embodiment, magnetron sputtering equipment adapted to a planar target is provided. With reference to FIG. 1, magnetron sputtering equipment includes a vacuum chamber 22, a pedestal 24, a target 28 and the magnetron apparatus according to any one of the embodiments as described above. The target 28 is configured to vacuum seal a backing plate 32 of a planar target 28 to a back chamber 34 through an insulating plate 36, and the back chamber is pumped to low pressure using a mechanical vacuum pump. Thus, the pressure differential across the large-area planar target 28 and the backing plate thereof is substantially eliminated, and the large amount of deformation caused by large pressure differentials is prevented. The target 28 is vacuum sealed to a vacuum chamber 22 by the insulating plate 30 as discussed above. The pedestal 24 is configured to hold a substrate 26 within the vacuum chamber 22 for deposition of a film layer thereon.

Several embodiments of the present invention have been described in detail with reference to the drawings, however, the present invention is not limited to the foregoing embodiments. Various changes can be made within the knowledge of those of ordinary skill in the art without departing from the essence of the present invention. In addition, the embodiments and features in the embodiments of the present invention can be combined with each other without conflict.

1. A scanning magnetron device for a Physical Vapor Deposition (PVD) planar target, comprising:
a magnetron, comprising an outer magnetic pole and an inner magnetic pole, wherein a polarity of the outer magnetic pole facing the target is opposite to that of the inner magnetic pole also facing the target, the outer magnetic pole comprises an outer linear portion and an outer semicircular portion connected to an end part of the outer linear portion, the inner magnetic pole comprises an inner linear portion and an inner semicircular portion connected to an end part of the inner linear portion, each of two opposite sides of the inner linear portion is provided with the outer linear portion, a gap is formed between the inner linear portion and the outer linear portion, at least the outer linear portion and the inner linear portion form a linear section, at least the outer semicircular portion and the inner service Mar portion forms a semicircular section;
a driving device, configured to drive the magnetron to reciprocate along a first direction and a second direction, wherein the first direction is perpendicular to a linear direction along which the linear section extends, and the second direction is parallel to the linear direction along which the linear section extends;
wherein a distance L₁ that the magnetron scans along the first direction satisfies: L₁₂≥d, a distance L₂ that the magnetron scans along the second direction satisfies: 0.5d≤L₂≤2d, and d is a distance between center lines of the gaps on two opposite sides of the inner linear portion.

2. The scanning magnetron device according to claim 1, wherein scanning of the magnetron along the first direction is limited between an initial position and a first scanning limit position, and the scanning of the magnetron along the second direction is limited between another initial position and a second scanning limit position; and the magnetron is configured such that the semicircular section is concentric with a rounded corner of the planar target when the magnetron is positioned at the first scanning limit position and the second scanning limit position.

3. The scanning magnetron device according to claim 2, wherein the magnetron is configured such that, an outer edge of the magnetron extends beyond a preset distance from an outer edge of the planar target when the magnetron is positioned at the first scanning limit position or at the second scanning limit position.

4. The scanning magnetron device according to claim 2 1, wherein a magnetic field strength generated by the inner magnetic pole is nearly equal to, or greater than, that generated by the outer magnetic pole.

5. The scanning magnetron device according to claim 1, wherein the magnetron further comprises a middle magnetic pole; the middle magnetic pole comprises a middle linear portion; the middle linear portion is arranged in the gap; each of the outer linear portion, the inner linear portion and the middle linear portion comprises a plurality of magnets arranged along the second direction; the magnets in the outer linear portion, the inner linear portion and the middle linear portion are symmetrically distributed with a center line of the inner linear portion as a symmetry axis; both a connection line of the north and south poles of the magnet in the outer linear portion and a connection line of the north and south poles of the magnet in the inner linear portion are perpendicular to the planar target; a connection line of the north and south poles of the magnet in the middle linear portion is parallel to said planar target; two magnetic poles of the magnet in the middle linear portion face the outer linear portion and the inner linear portion respectively; the magnetic pole at the outside of the magnet in the middle linear portion is consistent with the magnetic pole of the magnet in the outer magnetic pole facing the planar target;
and the magnetic pole at the inside of the magnet in the middle linear portion is consistent with the magnetic pole of the magnet in the inner magnetic pole facing the planar target; and wherein the linear section is composed of at least the outer linear portion, the inner linear portion and the middle linear portion, and a maximum magnetic field strength generated at target sputter surface by the linear section is greater than a maximum magnetic field strength generated at target sputter surface by the semicircular section.

6. The scanning magnetron device according to claim 5, wherein an end part of the outer linear portion facing the outer semicircular portion comprises a plurality of sets of outer magnets along a direction from the outer linear portion to the outer semicircular portion; a magnetic field strength generated at target sputter surface by each of the plurality of sets of outer magnets decreases gradually from a first one of the plurality of sets of outer magnets to a last one of the plurality of sets of outer magnets; and a maximum magnetic field strength generated at target sputter surface by the semicircular section is not greater than a magnetic field strength generated at target sputter surface by the last one of the plurality of sets of outer magnets at the end part of the outer linear portion facing the outer semicircular portion.

7. The scanning magnetron device according to claim 6, wherein along a direction from the outer linear portion to the outer semicircular portion, the outer linear portion comprises at least one of the following arrangements:
a cross-sectional area of each set of the outer magnets parallel to the planar target decreases gradually from the first one of the plurality of sets of outer magnets to the last one of the plurality of sets of outer magnets;
a height of each set of the outer magnets decreases gradually from the first one of the plurality of sets of outer magnets to the last one of the plurality of sets of outer magnets;
a distance between each set of the outer magnets and the planar target increases gradually from the first one of the plurality of sets of outer magnets to the last one of the plurality of sets of outer magnets; or
each set of the outer magnets is made of different materials with magnetic field strength weakened gradually from the first one of the plurality of sets of outer magnets to the last one of the plurality of sets of outer magnets.

8. The scanning magnetron device according to claim 5, wherein an end part of the inner linear portion facing the semicircular portion comprises a plurality of sets of inner magnets corresponding to the plurality of sets of outer magnets, and along a direction from the inner linear portion to the inner semicircular portion, a distance between each of the two sides of each set of inner magnets corresponding to the plurality sets of outer magnets and a center line of the inner linear portion increases gradually from a first one of the plurality of sets of inner magnets to a last one of the plurality of sets of inner magnets.

9. The scanning magnetron device according to claim 8, wherein the inner magnetic pole further comprises an inner semicircular portion, the outer semicircular portion and the inner semicircular portion form the semicircular section, an end part of the inner linear portion facing the semicircular section comprises two inner magnet arrays, the inner magnet arrays each comprise a plurality of sets of inner magnets, and the inner semicircular portion is connected to end parts of the two inner magnet arrays; and a distance between adjacent inner magnet arrays gradually increases from a first one of inner magnet arrays to a last one of the inner magnet arrays, along a direction from the inner linear portion to the semicircular section.

10. The scanning magnetron device according to claim 1, wherein the outer magnetic pole comprises a first connecting unit, a plurality of outer linear portions and a plurality of outer semicircular portions; the plurality of outer linear portions are arranged in parallel along the first direction at intervals, one end of the adjacent outer linear portions is connected by the outer semicircular portion, and the other end of the two outer linear portions at outermost sides along the first direction is arc-connected with the first connecting unit; and the inner magnetic pole comprises a second connecting unit and a plurality of inner linear portions, the plurality of inner linear portions are arranged in parallel along the first direction at intervals, the outer linear portions and the inner linear portions are alternately distributed along the first direction, and one side of each inner linear portion facing the first connecting unit is connected through the second connecting unit.

11. A magnetron sputtering apparratus, comprising:
a vacuum chamber;
the scanning magnetron device for the PVD planar target according to claim 1;
a planar target in the vacuum chamber; and
a pedestal configured to support a substrate in the vacuum chamber.
